(19) United States
(12) Patent Application Publication
(10) Pub. No.: US 2015/0340164 A1
(43) Pub. Date: Nov. 26, 2015

(54) PHOTOELECTRIC CONVERTER

(71) Applicant: Panasonic Corporation, Osaka (JP)

(72) Inventors: MICHIO SUZUKA, Osaka (JP); MASAHIRO TAKAHATA, Osaka (JP); NAOKI HAYASHI, Osaka (JP)

(21) Appl. No.: 14/711,787

(22) Filed: May 14, 2015

(30) Foreign Application Priority Data
May 21, 2014 (JP) 2014-105023

(51) Int. Cl. H01G 9/20; H01L 51/00

(52) U.S. Cl. CPC H01G 9/2004; H01G 9/2031; H01G 9/2059; H01L 51/0067; H01L 51/0072

(57) ABSTRACT

A photoelectric converter according to an aspect of the present disclosure comprises a photoanode including a semiconductor layer and a dye molecule located on the semiconductor layer, the dye molecule having a HOMO level nobler than +1.0 V measured against a Ag/Ag⁺ reference electrode; a counter electrode opposing the photoanode; and an electrolytic solution located between the photoanode and the counter electrode, the electrolytic solution containing a radical compound in which a carbon atom of one selected from the group consisting of an alkyl group and an alkylene group each having two or more carbon atoms is chemically bonded to the 4-position of a 2,2,6,6-tetramethylpiperidine 1-oxyl.

### BACKGROUND

1. Technical Field

The present disclosure relates to a photosensitized photoelectric converter. Throughout the specification, the term “photosensitized photoelectric converter” includes dye-sensitized solar cells and also includes dye-sensitized power generating elements that can generate electricity even in relatively low illuminance environments, such as indoors.

2. Description of the Related Art

In recent years, dye-sensitized solar cells using dyes as the photosensitizers have been researched and developed. A typical known dye-sensitized solar cell includes a photoanode containing a dye, a counter electrode, and an electrolytic solution disposed between the photoanode and the counter electrode and containing a redox pair. In order to improve the characteristics of the dye-sensitized solar cell, improvement in the characteristics of each component is required.

Japanese Unexamined Patent Application Publication No. 2003-100360 discloses a photoelectric converter including 2,2,6,6-tetramethylpiperidine 1-oxyl (hereinafter, referred to as “TEMPO”) as a mediator, and discloses that TEMPO is a compound having a stable radical site (nitroxyl radical) and causing a reversible redox reaction and can improve the photocharge separation efficiency of a photoelectric converter by the high electron self-exchanging reaction rate.

International Publication No. WO2011/013760 discloses stabilization of a photoelectric converter by increasing the molecular weight of a radical compound including TEMPO to gelate the electrolyte medium and thereby inhibiting volatilization of the radical compound.

### SUMMARY

One non-limiting and exemplary embodiment provides a photoelectric converter having a high conversion efficiency and high stability.

In one general aspect, the techniques disclosed here feature a photoelectric converter comprising: a photoanode including a semiconductor layer and a dye molecule located on the semiconductor layer, the dye molecule having a HOMO level nobler than +1.0 V measured against a Ag/Ag⁺ reference electrode; a counter electrode opposing the photoanode; and an electrolytic solution located between the photoanode and the counter electrode, the electrolytic solution containing a radical compound in which a carbon atom of one selected from the group consisting of an alkyl group and an alkylene group each having two or more carbon atoms is chemically bonded to the 4-position of a 2,2,6,6-tetramethylpiperidine 1-oxyl.

It should be noted that general or specific embodiments may be implemented as a device, a system, a method, or any selective combination thereof.

In one aspect of the present disclosure, a photoelectric converter including an electrolytic solution containing a compound including TEMPO as a mediator can be improved in the stability while maintaining a high conversion efficiency.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a diagram schematically illustrating a structure of the photoelectric converter 100 according to an embodiment of the present disclosure; and

FIG. 2 is a graph showing a relationship between a simulated SOMO level and the actually measured redox potential measured against a Ag/Ag⁺ reference electrode.

### DETAILED DESCRIPTION

The results of investigation by the present inventor revealed that although the photoelectric converter described in International Publication No. WO2011/013760 shows inhibited volatilization of the radical compound and improved stability, it has a problem of a reduction in the photoelectric conversion efficiency (hereinafter, simply referred to as “conversion efficiency”).

The present disclosure has been made for solving the above-mentioned problems, and provides a photoelectric converter having a high conversion efficiency and high stability.

The present disclosure provides the following aspects:

[Aspect 1] A photoelectric converter comprising:

a photoanode including a semiconductor layer and a dye molecule located on the semiconductor layer, the dye molecule having a HOMO level nobler than +1.0 V measured against a Ag/Ag⁺ reference electrode;

a counter electrode opposing the photoanode; and

an electrolytic solution located between the photoanode and the counter electrode, the electrolytic solution containing a radical compound in which a carbon atom of one selected from the group consisting of an alkyl group and an alkylene group each having two or more carbon atoms is chemically bonded to the 4-position of a 2,2,6,6-tetramethylpiperidine 1-oxyl;

[Aspect 2] The photoelectric converter according to Aspect 1, wherein an absolute value of a difference between a redox potential of the radical compound and a redox potential of the 2,2,6,6-tetramethylpiperidine 1-oxyl is +10 mV or less;
[Aspect 3] The photoelectric converter according to any one of Aspects 1 to 2, wherein

the electrolytic solution contains the radical compound in which the carbon atom of the alkylene group having two or more carbon atoms is chemically bonded to the 4-position of the 2,2,6,6-tetramethylpiperidine 1-oxyl, and

a functional group selected from the group consisting of an amino group, a vinyl group, an alkoxy group, a hydroxy group, a carboxyl group, an amido group, an ester group, and a cyano group is bonded to the alkylene group; and

[Aspect 4] The photoelectric converter according to Aspect 1, wherein the dye molecule is an indoline-based dye molecule.

### Embodiments

Embodiments of the present disclosure will now be described with reference to the drawings.

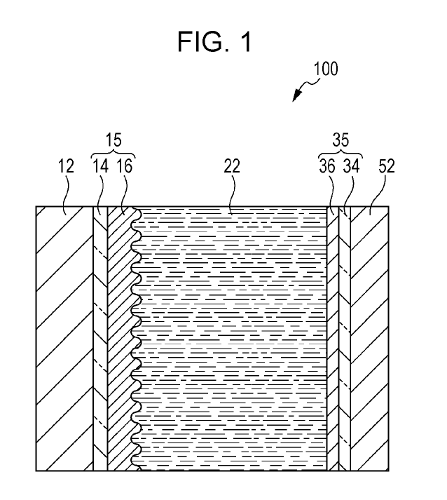

FIG. 1 schematically shows a structure of the photoelectric converter 100 according to an embodiment of the present disclosure. The photoelectric converter 100 includes a photoanode 15, a counter electrode 35, and an electrolytic solution 22 disposed between the photoanode 15 and the counter electrode 35.

The photoanode 15 is supported by a substrate 12 and includes, for example, an electrically conductive layer 14 capable of transmitting visible light (which may be also referred to as “transparent conductive layer”) and a solid semiconductor layer 16 disposed on the conductive layer 14. The solid semiconductor layer 16 contains a dye serving as a photosensitizer. The solid semiconductor layer 16 is, for example, a porous semiconductor layer and can be made of porous titanium oxide. The solid semiconductor layer 16 may be simply referred to as semiconductor layer 16.

The counter electrode 35 is disposed so as to oppose the semiconductor layer 16 with the electrolytic solution 22 therebetween. The counter electrode 35 is supported by a substrate 52 and includes, for example, an electrically conductive oxide layer 34 and a metal layer (e.g., platinum layer) 36 disposed on the conductive oxide layer 34.

The electrolytic solution 22 contains a radical compound serving as a mediator. The electrolytic solution 22 is sealed between the photoanode 15 and the counter electrode 35 with a sealing member (not shown).

In the radical compound contained in the electrolytic solution 22, a carbon atom of an alkyl or alkylene group having two or more carbon atoms is chemically bonded to the 4-position of TEMPO. As described in detail below, the photoelectric converter including such a radical compound can improve the stability while maintaining its high conversion efficiency. A compound composed of TEMPO and a functional group bonded to a part of TEMPO may be referred to as “TEMPO derivative”.

Materials that are used in the formation of each component of the photoelectric converter 100 will now be described in detail.

### Photoanode

The photoanode 15 functions as a negative electrode of the photoelectric converter 100. As described above, the photoanode 15 includes, for example, an electrically conductive layer 14 capable of transmitting visible light and a semiconductor layer 16 disposed on the conductive layer 14. The semiconductor layer 16 contains a photosensitizer. The semiconductor layer 16 containing a photosensitizer is also called light absorbing layer. The substrate 12 is, for example, a glass substrate or plastic substrate (or plastic film) that can transmit visible light.

The electrically conductive layer 14 capable of transmitting visible light can be formed from, for example, a material that transmits visible light (hereinafter, referred to as “transparent conductive material”). Examples of the transparent conductive material include zinc oxide, indium-tin complex oxide, laminate composed of indium-tin complex oxide layer and silver layer, tin oxide doped with antimony, and tin oxide doped with fluorine. Among them, tin oxide doped with fluorine is desirable because of its particularly high conductive property and translucency. A conductive layer 14 having higher transmissibility is desirable, and the transmissibility is desirably 50% or more and more desirably 80% or more.

The conductive layer 14 has a thickness, for example, within a range of 0.1 to 10 μm. Within this range, the conductive layer 14 can have a uniform thickness and can maintain the optical transparency for allowing a sufficient amount of light to enter the semiconductor layer 16. A conductive layer 14 having lower surface resistance is desirable, and the surface resistance is desirably 200Ω/□ or less and more desirably 50Ω/□ or less. The lower limit is not particularly determined and is, for example, 0.1Ω/□. Many of photoelectric converters that are used under sunlight have a surface resistance of approximately 10Ω/□. In the photoelectric converter 100 that is used under an illuminance lower than that of sunlight, for example, under a fluorescent light, however, since the amount of photoelectrons (photocurrent value) is small, harmful influence on the photoelectric converter 100 by the resistance component contained in the conductive layer 14 is low. Accordingly, in the photoelectric converter 100 that is used under a low illuminance environment, the surface resistance of the conductive layer 14 may be within a range of 30 to 200Ω/□ from the viewpoint of reducing the cost through a reduction in the amount of the conductive material contained in the conductive layer 14.

The electrically conductive layer 14 capable of transmitting visible light can also be formed from a conductive material not having translucency, such as a metal layer having a linear (stripe), wave, lattice (mesh), or perforated (referring to a large number of regularly or irregularly arranged fine through-holes) pattern or a metal layer having a pattern reverse to any one of the above-mentioned patterns. In these metal layers, light can pass through the region where no metal is present. Examples of the metal include platinum, gold, silver, copper, aluminum, rhodium, indium, titanium, iron, nickel, tin, zinc, and alloys containing these metals. Instead of these metals, a carbon material having a conductive property can also be used.

The transmissibility of the electrically conductive layer 14 capable of transmitting visible light is, for example, 50% or more and may be 80% or more. The wavelength of light to be transmitted varies depending on the absorption wavelength of the photosensitizer.

When light enters the semiconductor layer 16 from the opposite side of the substrate 12, the substrate 12 and the conductive layer 14 need not transmit visible light. In such a case, therefore, if the above-mentioned metal or carbon material is used in formation of the conductive layer 14, the region not having the metal or carbon material is not necessary. Furthermore, if such a material has a sufficient strength, the conductive layer 14 may also serve as the substrate 12.

In order to prevent leakage of electrons from the surface of the conductive layer 14, i.e., in order to provide rectification between the conductive layer 14 and the semiconductor layer 16, an oxide layer may be disposed between the conductive layer 14 and the semiconductor layer 16. Examples of the oxide include silicon oxide, tin oxide, titanium oxide, zirconium oxide, and aluminum oxide.

The semiconductor layer 16 containing a photosensitizer includes, for example, a porous semiconductor and a photosensitizer supported on the surface of the porous semiconductor. The porous semiconductor is, for example, porous titanium oxide (TiO₂). Titanium oxide has high photoelectric conversion characteristics and hardly causes photodissolution in an electrolyte solution. A porous material has a large specific surface area and has an advantage of being capable of supporting a large amount of a photosensitizer. The semiconductor layer 16 may be made of, for example, aggregated semiconductor particles, instead of porous materials.

The particle diameter of the semiconductor particle may be within a range of 5 to 1000 nm and is desirably within a range of 10 to 100 nm. A particle diameter within a range of 5 to 1000 nm can form a semiconductor layer 16 having a surface area that can adsorb a sufficient amount of a photosensitizer and can enhance the efficiency of utilizing light. In addition, since the semiconductor layer 16 can have appropriately sized holes, an electrolytic solution (electrolyte medium or charge-transporting material) sufficiently permeates into the semiconductor layer 16 to give excellent photoelectric conversion characteristics.

The semiconductor layer 16 may have a thickness of 0.1 to 100 μm, desirably 1 to 50 μm, more desirably 3 to 20 μm, and most desirably 5 to 10 μm. A thickness of the semiconductor layer 16 within this range can provide a sufficient photoelectric conversion effect and can also sufficiently secure transparency for visible light and infrared light. In this photoelectric converter 100, the thickness of the semiconductor layer 16 may be smaller than the optimal thicknesses (e.g., 10 μm) of the semiconductor layers of the above-mentioned known photoelectric converters that are used under sunlight.

The semiconductor layer 16 has a thickness of, for example, 0.01 μm or more and 100 μm or less. The thickness of the semiconductor layer 16 can be appropriately varied in view of the efficiency of photoelectric conversion and is desirably 0.5 μm or more and 50 μm or less and more desirably 1 μm or more and 20 μm or less. A larger surface roughness of the semiconductor layer 16 is desirable. The coefficient of surface roughness defined by dividing an effective area by the projected area is desirably 10 or more and more desirably 100 or more. The effective area refers to an effective surface area that is determined from the volume, which is determined from the projected area and thickness of the semiconductor layer 16, and the specific surface area and bulk density of the material of the semiconductor layer 16.

The semiconductor layer 16 may be formed from an inorganic semiconductor, instead of TiO₂. Examples of the inorganic material include oxides of metal elements such as Cd, Zn, In, Pb, Mo, W, Sb, Bi, Cu, Hg, Ti, Ag, Mn, Fe, V, Sn, Zr, Sr, Ga, Si, and Cr; perovskites such as SrTiO₃ and CaTiO₃; sulfides such as CdS, ZnS, In₂S₃, PbS, Mo₂S, WS₂, Sb₂S₃, Bi₂S₃, ZnCdS₂, and Cu₂S; metal chalcogenides such as CdSe, In₂Se₃, WSe₂, HgS, PbSe, and CdTe; and other inorganic materials such as GaAs, Si, Se, Cd₂P₃, Zn₂P₃, InP, AgBr, PbI₂, HgI₂, and BiI₃. Among them, CdS, ZnS, In₂S₃, PbS, Mo₂S, WS₂, Sb₂S₃, Bi₂S₃, ZnCdS₂, Cu₂S, InP, Cu₂O, CuO, and CdSe advantageously absorb light having a wavelength of approximately 350 to 1300 nm. A complex containing at least one selected from the above-mentioned semiconductors can also be used. Examples of the complex include CdS/TiO₂, CdS/AgI, Ag₂S/AgI, CdS/ZnO, CdS/HgS, CdS/PbS, ZnO/ZnS, ZnO/ZnSe, CdS/HgS, CdSₓ/CdSe₁₋ₓ, CdSₓ/Te₁₋ₓ, CdSeₓ/Te₁₋ₓ, ZnS/CdSe, ZnSe/CdSe, CdS/ZnS, TiO₂/Cd₃P₂, CdS/CdSeCd_{y}Zn_{1-y}S, and CdS/HgS/CdS. Furthermore, organic semiconductors, such as poly(phenylene vinylene), polythiophene, polyacetylene, tetracene, pentacene, and phthalocyanine, can be used. Viologen polymers and quinone polymers may also be used.

Alternatively, the semiconductor layer 16 may be an organic compound having a redox site that can repeatedly undergo a redox reaction in a part of the molecule and a site that can be swollen with an electrolyte solution to form a gel layer in another part of the molecule (see, for example, International Publication No. WO2010/024090).

The semiconductor layer 16 can be formed by various known methods. In a case of using an inorganic semiconductor, for example, a semiconductor layer 16 made of an inorganic semiconductor can be prepared by applying a mixture of a semiconductor material powder and an organic binder (including an organic solvent) onto the conductive layer 14 and then removing the organic binder by heat treatment. The mixture can be applied by any known application or printing method. Examples of the application method include doctor blade, bar coating, spraying, dip coating, and spin coating. Examples of the printing include screen printing. The film of the mixture may be optionally pressed.

In also a case of using an organic semiconductor, the semiconductor layer 16 can be formed by various known methods. A solution of an organic semiconductor may be applied onto the conductive layer 14 by a known application or printing method. For example, in a case of using a polymer semiconductor having a number-average molecular weight of 1000 or more, application, such as spin coating or drop casting, or printing, such as screen printing or gravure printing, can be employed. In addition to these wet processes, a dry process, such as sputtering or vapor deposition, can also be employed.

Examples of the photosensitizer include ultrafine semiconductor particles, dyes, and pigments. The photosensitizer may be an inorganic material, an organic material, or a mixture thereof. A dye is desirable from the viewpoint of efficiently absorbing light and separating charges. The dye desirably has a HOMO level at a potential nobler than +1.0 V measured against a Ag/Ag⁺ reference electrode. In the present disclosure, RE-7 manufactured by BAS Inc. is used as the Ag/Ag⁺ reference electrode. In a case of using such a dye, a combination of the dye and the radical compound of the present disclosure can efficiently transfer charges. Examples of the dye include 9-phenylxanthene, coumarin, acridine, triphenylmethane, tetraphenylmethane, quinone, azo, indigo, cyanine, indoline, merocyanine, and xanthene dyes. Other examples of the dye include ruthenium-cis-diaqua-bipyridyl complexes, such as RuL₂(H₂O)₂ (where L represents 4,4′-dicarboxyl-2,2′-bipyridine); transition metal complexes, such as ruthenium-tris (RuL₃), ruthenium-bis (RuL₂), osmium-tris (OsL₃), and osmiun-bis (OsL₂) complexes; and zinc-tetra(4-carboxyphenyl)porphyrin, iron-hexacyanide complexes, and phthalocyanine. In addition, dyes described in, for example, the chapter of “DSSC” in “Advanced Technologies and Material Development of FPD, DSSC, Optical Memory, and Functional Dye” (NTS Inc.) can be used. Among them, dyes having a characteristic to aggregate may densely aggregate to cover the surface of a semiconductor and may thereby function as an insulator layer. If the photosensitizer functions as an insulator layer, the charge separation interface (the interface between the photosensitizer and the semiconductor) can be rectified, and recombination of charges after charge separation can be inhibited.

The dye having a characteristic to aggregate desirably has a structure represented by formula Chem. 1, and a typical example thereof is a dye having the structure represented by formula Chem. 2. Whether a dye is in a form of aggregate or not can be easily judged by comparing the absorption spectrum of the dye dissolved in, for example, an organic solvent with the absorption spectrum of the dye supported on a semiconductor.

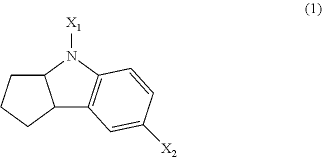

where X₁ and X₂ each independently include at least one group selected from the group consisting of alkyl, alkenyl, aralkyl, and aryl groups and hetero rings. And the at least one group each independently may have a substituent. X₂ includes, for example, a carboxyl group, a sulfonyl group, or a phosphonyl group.

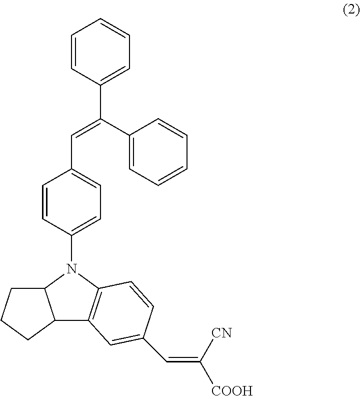 [SMILES: N#C/C(=C\c1ccc2c(c1)C1CCCC1N2c1ccc(C=C(c2ccccc2)c2ccccc2)cc1)C(=O)O]

Examples of the ultrafine semiconductor particle that can be used as the photosensitizer include ultrafine particles of sulfide semiconductors, such as cadmium sulfide, lead sulfide, and silver sulfide. The ultrafine semiconductor particle has a diameter of, for example, 1 to 10 nm.

The photosensitizer can be supported by a semiconductor by various known methods, for example, by immersing a substrate provided with a semiconductor layer (e.g., porous semiconductor not containing any photosensitizer) in a solution or dispersion of the photosensitizer. The solvent of the solution or dispersion can be appropriately selected from those that can dissolve or disperse the photosensitizer, such as water, alcohol, toluene, and dimethylformaldehyde. The immersion in a solution or dispersion of the photosensitizer may be performed with application of heat or ultrasonic waves. After the immersion, the excessive photosensitizer may be removed by rinsing with a solvent (e.g., alcohol) and/or heating.

The amount of the photosensitizer supported by the semiconductor 16 is, for example, within a range of 1×10⁻¹⁰ to 1×10⁻⁴ mol/cm² and may be, for example, within a range of 0.1×10⁻⁸ to 9.0×10⁻⁶ mol/cm² from the viewpoint of photoelectric conversion efficiency and cost.

Since the above-mentioned CdS, ZnS, In₂S₃, PbS, Mo₂S, WS₂, Sb₂S₃, Bi₂S₃, ZnCdS₂, Cu₂S, InP, Cu₂O, CuO, and CdSe can absorb light having a wavelength of approximately 350 to 1300 nm, the semiconductor layers formed from these compounds may contain no photosensitizer.

### Counter Electrode

The counter electrode 35 functions as a positive electrode of the photoelectric converter 100. Examples of the material for forming the counter electrode 35 include metals, such as platinum, gold, silver, copper, aluminum, rhodium, and indium; carbon materials, such as graphite, carbon nanotubes, and carbon supporting platinum; electrically conductive metal oxides, such as indium-tin complex oxide, tin oxide doped with antimony, and tin oxide doped with fluorine; and electrically conductive polymers, such as polyethylenedioxythiophene, polypyrrole, and polyaniline. Among them, platinum, graphite, and polyethylenedioxythiophene are desirable.

As shown in FIG. 1, the counter electrode 35 may have a transparent conductive layer 34 on the substrate 52 side. The transparent conductive layer 34 can be formed from the same material as that of the conductive layer 14 of the photoanode 15. In such a case, the counter electrode 35 may also be transparent. If the counter electrode 35 is transparent, light can be received on the substrate 52 side and the substrate 12 side. This is effective when photoirradiation from the front and back surfaces of the photoelectric converter 100 is expected due to influence of, for example, reflection light.

### Electrolytic Solution

The electrolytic solution 22 contains a radical compound as the mediator. The radical compound contained in the electrolytic solution 22 is a compound in which a carbon atom of an alkyl or alkylene group having two or more carbon atoms is chemically bonded to the 4-position of TEMPO. The use of such a radical compound can improve the stability while maintaining the high conversion efficiency of the photoelectric converter. The redox potential of the radical compound is +0.67 V or less measured against a Ag/Ag⁺ reference electrode, and an absolute value of its difference from the redox potential of TEMPO is +10 mV or less. The carbon atom is derived from, for example, an alkyl group. Alternatively, the carbon atom is derived from, for example, an alkylene group that is bonded to a functional group selected from the group consisting of amino, vinyl, alkoxy, hydroxy, carboxyl, amido, ester, and cyano groups. The radical compound may have two or more structures, in each of which an alkylene group is bonded to the 4-position of TEMPO, in one molecule. That is, the radical compound may have a structure including two or more TEMPOs, each to which an alkylene group is bonded at the 4-position, being bonded to each other through the above-mentioned functional group.

The radical compound contained in the electrolytic solution that is included in the photoelectric converter of the present disclosure will be described in detail below by showing the results of experiments and simulation.

The solvent is desirably a compound that dissolves the radical compound and has excellent ion conductivity. The solvent may be an aqueous solvent or an organic solvent and is desirably an organic solvent for more stabilizing the radical compound. Examples of the solvent include carbonate compounds, such as dimethyl carbonate, diethyl carbonate, methyl ethyl carbonate, ethylene carbonate, and propylene carbonate; ester compounds, such as methyl acetate, methyl propionate, and γ-butyrolactone; ether compounds, such as diethyl ether, 1,2-dimethoxyethane, 1,3-dioxosilane, tetrahydrofuran, and 2-methyl-tetrahydrofuran; heterocyclic compounds, such as 3-methyl-2-oxazolidinone and 2-methylpyrrolidone; nitrile compounds, such as acetonitrile, methoxyacetonitrile, and propionitrile; and aprotonic polar compounds, such as sulfolane, dimethyl sulfoxide, and dimethylformamide. These solvents may be used alone or in combination of two or more thereof. In particular, carbonate compounds, such as ethylene carbonate and propylene carbonate; heterocyclic compounds, such as γ-butyrolactone, 3-methyl-2-oxazolidinone, and 2-methylpyrrolidone; and nitrile compounds, such as acetonitrile, methoxyacetonitrile, propionitrile, 3-methoxypropionitrile, and valeric acid nitrile are desirable.

The use of a solvent that is an ionic solution or a mixture of an ionic solution and another solvent particularly stabilizes the redox site (nitroxyl radical of TEMPO). In addition, the ionic solution is non-volatile and highly flame retardant and thereby has excellent stability. The ionic solution may be any known ionic solution, and examples thereof include imidazolium-based, such as 1-ethyl-3-methylimidazolium tetracyanoborate, pyridine-based, alicyclic amine-based, aliphatic amine-based, and azoniumamine-based ionic solutions; and ionic solutions described in European Patent No. 718288, International Publication No. WO95/18456, Denkikagaku (Electrochemistry), Vol. 65, No. 11, p. 923 (1997), J. Electrochem. Soc., Vol. 143, No. 10, p. 3099 (1996), and Inorg. Chem., Vol. 35, p. 1168 (1996).

The radical compound contained in the electrolytic solution that is included in the photoelectric converter of the present disclosure will be described in detail by showing the results of experiments and simulation.

In the simulation, the energy level of singly occupied molecular orbital (SOMO) of a TEMPO derivative having a substituent at the 4-position was determined. The SOMO corresponds to the highest occupied molecular orbital (HOMO) of a neutral molecule. The calculation was performed with Gaussian 09. Gaussian 09 corresponds to Gaussian 03, Revision shown below. The calculation was performed by a density functional theory (DFT) using functional PBE1PBE and basis function 6-31+G*. In addition, the solvent effect of acetonitrile was considered by a polarizable continuum model (PCM). The structure of the TEMPO derivative was optimized by the above-mentioned conditions, and the energy level of SOMO was then determined.

Gaussian 03, Revision C.02, M. J. Frisch, G. W. Trucks, H. B. Schlegel, G. E. Scuseria, M. A. Robb, J. R. Cheeseman, J. A. Montgomery, Jr., T. Vreven, K. N. Kudin, J. C. Burant, J. M. Millam, S. S. Iyengar, J. Tomasi, V. Barone, B. Mennucci, M. Cossi, G. Scalmani, N. Rega, G. A. Petersson, H. Nakatsuji, M. Hada, M. Ehara, K. Toyota, R. Fukuda, J. Hasegawa, M. Ishida, T. Nakajima, Y. Honda, O. Kitao, H. Nakai, M. Klene, X. Li, J. E. Knox, H. P. Hratchian, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, P. Y. Ayala, K. Morokuma, G. A. Voth, P. Salvador, J. J. Dannenberg, V. G. Zakrzewski, S. Dapprich, A. D. Daniels, M. C. Strain, O. Farkas, D. K. Malick, A. D. Rabuck, K. Raghavachari, J. B. Foresman, J. V. Ortiz, Q. Cui, A. G. Baboul, S. Clifford, J. Cioslowski, B. B. Stefanov, G. Liu, A. Liashenko, P. Piskorz, I. Komaromi, R. L. Martin, D. J. Fox, T. Keith, M. A. Al-Laham, C. Y. Peng, A. Nanayakkara, M. Challacombe, P. M. W. Gill, B. Johnson, W. Chen, M. W. Wong, C. Gonzalez, and J. A. Pople, Gaussian, Inc., Wallingford Conn., 2004.

The redox potential of another TEMPO derivative having another functional group bonded to the 4-position of TEMPO was similarly determined by simulation. The amount of shift of the redox potential of each TEMPO derivative from the redox potential of TEMPO is shown in Table 1.

As obvious from Table 1, the redox potential of every TEMPO derivative shifted to the positive side (nobler side). All of the functional groups shown in Table 1 (from the upper side of Table 1, amino, vinyl, alkoxy (ether), hydroxy, carboxyl, amido, ester, and cyano groups) have electron-withdrawing properties. These functional groups are introduced when TEMPO is linked to the main chain of a polymer, in the polymerized radical compounds described in International Publication No. WO2011/013760. This suggests that one cause of that the photoelectric converter described in International Publication No. WO2011/013760 has a low conversion efficiency is a reduction in current value due to a shift of the redox potential of the radical compound (mediator) to the positive side.

In contrast, as shown in Table 2, when the functional group bonded to the 4-position of TEMPO is an alkyl groups having two or more carbon atoms, the redox potential of the TEMPO derivative shifts to the negative (baser side). There is a tendency that the absolute value of the amount of shift increases with the number of the carbon atoms of the alkyl group. The absolute value of the amount of shift is high when a quaternary carbon (—C(CH₃)₃) is bonded to the 4-position of TEMPO. And the absolute value of the amount of shift seems to increase with the number of carbons which are bonded to the carbon bonded to the 4-position of TEMPO.

When an alkylene group having two or more carbon atoms is introduced between a hydroxy group and the carbon at the 4-position of TEMPO, the amount of the shift of the redox potential of the TEMPO derivative is +35 mV. The amount is smaller (baser side) than the amount of the shift of the redox potential, +100 mV, of the TEMPO derivative in which a hydroxy group is directly bonded to the carbon at the 4-position of TEMPO. Thus, the introduction of an alkylene group having two or more carbon atoms seems to have an effect of shifting the redox potential of each TEMPO derivative to the negative side, as in the introduction of an alkyl group.

TABLE 1

| Functional group | Shift of redox potential (mV) |
|---|---|
| —NH₂ | +40 |
| —CH═CH₂ | +45 |
| —O—CH₂—CH₃ | +80 |
| —OH | +100 |
| —COOH | +120 |
| —NHCOCH₃ | +130 |
| —OCO—CH₂—CH₃ | +140 |
| —CN | +200 |

TABLE 2

| | Shift of redox |
|---|---|
| Functional group | potential (mV) |
| —C(CH₃)₃ | −10 |
| —(CH₂)₄—CH₃ | −4 |
| —(CH₂)₃—CH₃ | −4 |
| —(CH₂)₂—CH₃ | −3 |
| —CH₂—CH₃ | −3 |
| —(CH₂)₂—OH | +35 |
| —(CH₂)₂—OCO—(CH₂)₄—COO—(CH₂)₂-TEMPO | +35 |

The results of the simulation are also supported by experiments. Examples and comparative examples are shown below. Each TEMPO derivative having a functional group at the 4-position of TEMPO can be synthesized by, for example, the method described in Liebigs, Ann. Chem., 1987, 777-780.

The characteristics of photoelectric converters produced in Examples 1 to 3 and Comparative Examples 1 to 4 were evaluated. The results are collectively shown in Table 3.

### Example 1

A photoelectric converter having substantially the same structure as that of the photoelectric converter shown in FIG. 1 was produced. Each component was as follows:

Substrate: glass substrate having a thickness of 1 mm, Transparent conductive layer: fluorine-doped SnO₂ layer (surface resistance: 10Ω/□),

Semiconductor layer: porous titanium oxide, photosensitive dye (D131, manufactured by Mitsubishi Paper Mills Limited),

Counter electrode: mesh platinum electrode,

Electrolyte solution: acetonitrile containing 0.025 mol/L of N-methylbenzimidazole, 0.1 mol/L of lithium perchlorate, and 0.01 mol/L (10 mM) of 4-C₂H₄OH-TEMPO (represented by formula Chem. 3),

Substrate: glass substrate having a thickness of 1 mm, Conductive oxide layer: fluorine-doped SnO₂ layer (surface resistance: 10Ω/□), and

Metal layer: platinum layer.

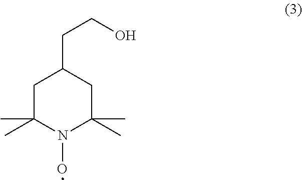

The photoelectric converter of Example 1 was produced as follows.

Two conductive glass substrates (manufactured by Asahi Glass Co., Ltd.) each provided with a fluorine-doped SnO₂ layer having a thickness of 1 mm were prepared. These substrates were used as a substrate 12 having a transparent conductive layer 14 and a substrate 52 having a conductive oxide layer 34.

A high-purity titanium oxide powder having a mean primary particle diameter of 20 nm was dispersed in ethyl cellulose to prepare a paste for screen printing.

A titanium oxide layer having a thickness of approximately 10 nm was formed by sputtering on the fluorine-doped SnO₂ layer of one of the conductive glass substrates. The paste prepared above was then applied onto the titanium oxide layer, followed by drying. The resulting dry matter was fired in the air at 500° C. for 30 minutes to form a porous titanium oxide layer (titanium coat) having a thickness of 2 μm. The porous titanium oxide layer had a surface roughness of approximately 250 μm.

The substrate provided with the porous titanium oxide layer was then immersed in a solvent mixture of acetonitrile and butanol (1:1) containing 0.3 mM photosensitive dye (D131, manufactured by Mitsubishi Paper Mills Limited) represented by formula Chem. 2, followed by leaving to stand at room temperature for 16 hours in a dark place to allow the photosensitizer to be supported by the porous titanium oxide layer. Thus, a photoanode 15 was formed.

A metal layer 36 was formed on the surface of the other conductive glass substrate by depositing platinum by sputtering.

Subsequently, a sealing material, which was a hot-melt adhesive (manufactured by Du Pont-Mitsui Polychemicals Co., Ltd.), was arranged on the charge storage electrode so as to surround the portion of the photoanode at which the porous titanium oxide layer was formed. The glass substrate provided with the photoanode was then placed on the sealing material and was bonded to the other conductive glass substrate provided with the charge storage electrode by pressing with heating. The glass substrate provided with the charge storage electrode was provided with a hole with a diamond drill in advance.

An electrolyte solution was prepared by dissolving 0.025 mol/L of N-methylbenzimidazole, 0.1 mol/L of lithium perchlorate, and 0.01 mol/L of 4-methyl-2,2,6,6-tetramethylpiperidine 1-oxyl in acetonitrile. This electrolyte solution was injected between the electrodes through the hole, and the hole was then sealed by a UV curable resin. Thus, a photoelectric converter of Example 1 was produced.

### Example 2

A photoelectric converter of Example 2 was produced as in Example 1 except that the photosensitizer used was D358 (manufactured by Mitsubishi Paper Mills Limited) represented by formula Chem. 4.

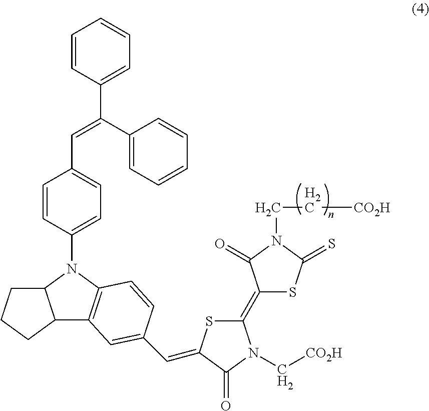

### Example 3

A photoelectric converter of Example 3 was produced as in Example 2 except that acetonitrile containing 0.01 mol/L (10 mM) of 4-CH₃—COO—CH₂-TEMPO (represented by formula Chem. 5), 0.025 mol/L of N-methylbenzimidazole, and 0.1 mol/L of lithium perchlorate was used as the electrolyte solution.

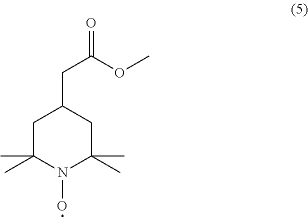

### Comparative Example 1

A photoelectric converter of Comparative Example 1 was produced as in Example 2 except that acetonitrile containing 0.01 mol/L (10 mM) of TEMPO, 0.025 mol/L of N-methylbenzimidazole, and 0.1 mol/L of lithium perchlorate was used as the electrolyte solution.

### Comparative Example 2

A photoelectric converter of Comparative Example 2 was produced as in Example 2 except that acetonitrile containing 0.01 mol/L (10 mM) of 4-cyano-TEMPO, 0.025 mol/L of N-methylbenzimidazole, and 0.1 mol/L of lithium perchlorate was used as the electrolyte solution.

### Comparative Example 3

A photoelectric converter of Comparative Example 3 was produced as in Example 2 except that acetonitrile containing 0.01 mol/L (10 mM) of 4-hydroxy-TEMPO, 0.025 mol/L of N-methylbenzimidazole, and 0.1 mol/L of lithium perchlorate was used as the electrolyte solution.

### Comparative Example 4

A photoelectric converter of Comparative Example 4 was produced as in Example 2 except that acetonitrile containing 0.01 mol/L (10 mM) of 4-NHCOCH₃-TEMPO (represented by formula Chem. 6), 0.025 mol/L of N-methylbenzimidazole, and 0.1 mol/L of lithium perchlorate was used as the electrolyte solution.

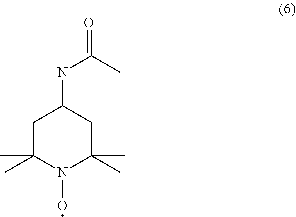

### Evaluation Method

Sublimability was evaluated as follows.

Each radical compound (mediator) was placed in a petri dish and was left to stand at 25° C. for 24 hours, and the change in mass was then measured.

TABLE 3

| | | | Redox | | | | |
|---|---|---|---|---|---|---|---|
| | | | potential | Photosen- | Voc | Jsc | Pmax |
| | | Sublimability | (vs. Ag/Ag⁺) | sitizer | (mV) | (μA/cm²) | (μW/cm²) |
| Example 1 | C₂H₄OH-TEMPO | 0% | 0.67 | D131 | 710 | 18 | 9.3 |
| Example 2 | C₂H₄OH-TEMPO | 0% | 0.67 | D358 | 720 | 17 | 9.2 |
| Example 3 | CH₃—COO—CH₂-TEMPO | 0% | 0.66 | D358 | 730 | 16 | 9.2 |
| Comparative | TEMPO | 4% | 0.66 | D358 | 720 | 17 | 9.2 |
| Example 1 | | | | | | | |
| Comparative | CN-TEMPO | 0% | 0.86 | D358 | 760 | 13 | 3.2 |
| Example 2 | | | | | | | |
| Comparative | OH-TEMPO | 0% | 0.7 | D358 | 730 | 14 | 6.3 |
| Example 3 | | | | | | | |
| Comparative | NHCOCH₃-TEMPO | 0% | 0.76 | D358 | 750 | 13 | 4.8 |
| Example 4 | | | | | | | |

The results shown in Table 3 demonstrated that the TEMPO derivatives of Examples 1 to 3 each had a redox potential of 0.66 V or more and 0.67 V or less measured against a Ag/Ag⁺ reference electrode, which is equivalent to that of TEMPO, and that these TEMPO derivatives have low sublimability, unlike TEMPO.

The results demonstrated that the photoelectric converters of Examples 1 to 3 had high stability while maintaining the high conversion efficiencies, compared to the photoelectric converter Comparative Example 1.

These results indicated that the photoelectric converters of Examples 1 to 3 have high conversion efficiencies and high stability.

Since the amount of shift in the redox potential in simulation of each of the TEMPO derivatives used in Examples 1 and 2 is +35 mV, the above-described effects seem to be obtained if the amount of shift in the redox potential in simulation is +35 mV or less.

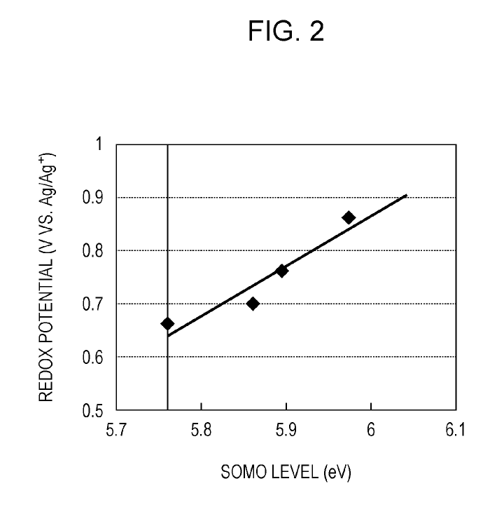

FIG. 2 shows a relationship between a simulated SOMO level and the actually measured redox potential measured against a Ag/Ag⁺ reference electrode. From FIG. 2, a high (primary) correlation is found between the simulated SOMO level and the actually measured redox potential. This means that an actual redox potential can be estimated from a simulated SOMO level or redox potential.

The TEMPO derivatives, shown in Table 2, in which a carbon atom of an alkyl or alkylene group having two or more carbon atoms is chemically bonded to the 4-position of TEMPO, are therefore presumed to have the above-described effects. An absolute value of the difference between the redox potential of each TEMPO derivative and the redox potential of TEMPO is +10 mV or less. The alkylene group may be bonded to any of amino, vinyl, alkoxy, hydroxy, carboxyl, amido, ester, and cyano groups. As shown in Table 2, the TEMPO derivative may have two or more structures, in each of which an alkylene group is bonded to the 4-position of TEMPO, in one molecule.

The photoelectric converter of the present disclosure can be used as, for example, a dye-sensitized power generating element that can generate electricity even in relatively low illuminance environments, such as indoors.

What is claimed is:

1. A photoelectric converter comprising:
a photoanode including a semiconductor layer and a dye molecule located on the semiconductor layer, the dye molecule having a HOMO level nobler than +1.0 V measured against a Ag/Ag⁺ reference electrode;
a counter electrode opposing the photoanode; and
an electrolytic solution located between the photoanode and the counter electrode, the electrolytic solution containing a radical compound in which a carbon atom of one selected from the group consisting of an alkyl group and an alkylene group each having two or more carbon atoms is chemically bonded to the 4-position of a 2,2,6,6-tetramethylpiperidine 1-oxyl.

2. The photoelectric converter according to claim 1, wherein an absolute value of a difference between a redox potential of the radical compound and a redox potential of the 2,2,6,6-tetramethylpiperidine 1-oxyl is +10 mV or less.

3. The photoelectric converter according to claim 1, wherein
the electrolytic solution contains the radical compound in which the carbon atom of the alkylene group having two or more carbon atoms is chemically bonded to the 4-position of the 2,2,6,6-tetramethylpiperidine 1-oxyl, and
a functional group selected from the group consisting of an amino group, a vinyl group, an alkoxy group, a hydroxy group, a carboxyl group, an amido group, an ester group, and a cyano group is bonded to the alkylene group.

4. The photoelectric converter according to claim 1, wherein the dye molecule is an indoline-based dye molecule.
